(19) United States
(12) Patent Application Publication
(10) Pub. No.: US 2026/0323840 A1
(43) Pub. Date: Oct. 15, 2026

(54) MICRO-NANOSCALE ADDITIVE MANUFACTURING METHOD AND PATTERNING METHOD

(71) Applicant: SHANGHAITECH UNIVERSITY, Shanghai (CN)

(72) Inventors: Jicheng FENG, Shanghai (CN); Yuxiang YIN, Shanghai (CN); Shirong LIU, Shangahi (CN)

(21) Appl. No.: 19/695,111

(22) Filed: Jun. 2, 2026

Related U.S. Application Data
(63) Continuation of application No. PCT/CN2023/143382, filed on Dec. 29, 2023.

(51) Int. Cl. B82B 3/00; B33Y 10/00; B33Y 70/10; B81C 1/00

(52) U.S. Cl. CPC B82B 3/0095; B81C 1/00373; B33Y 10/00; B33Y 70/10

(57) ABSTRACT

A micro-nanoscale additive manufacturing method, and a patterning method developed based on the micro-nanoscale additive manufacturing method. The additive manufacturing method is achieved by guiding the charged species dispersed in a gas. The charged phase dispersed in the gas passes through the channels in a layer with opening pattern arrays on a substrate. The accumulation of such charged species build up arrays of printed structures on the substrate and the structures have a smaller feature size than that of the channels. The substrate is made of an insulating material. To realize this, the electric field strength value at the printing position is controlled to be not less than 15000 V/cm, wherein the direction of the electric field is either positive or negative. The patterning method is achieved by transferring the printed structures formed on the substrate into the substrate.

### CROSS-REFERENCE TO RELATED APPLICATIONS

The present application is a continuation application of No. PCT/CN2023/143382, filed on Dec. 29, 2023.

### TECHNICAL FIELD

The present disclosure relates to a micro-nanoscale additive manufacturing method and a patterning method.

### BACKGROUND

Micro-nano fabrication technology is widely used in industries such as integrated circuits and micro-electromechanical devices. Currently, mainstream micro-nano fabrication technologies employ planar manufacturing methods based on patterning technologies, where the processing accuracy or minimum feature size is determined by the patterning technologies used during the processing.

Existing patterning technologies include photolithography, nanoimprint, and directed self-assembly technology. Among these, photolithography is the most widely used and is currently the patterning technology capable of achieving high resolution and large area through multiple exposures. Compared to photolithography, nanoimprint technology requires simple equipment but is limited by issues such as mold processing difficulty, mold lifespan, and contact-based processing. Directed self-assembly technology can process patterns smaller than 10 nm through density multiplication, but this method still faces many challenges in defect control, types of processable patterns, orientation guidance, and processing time.

Chinese Patent CN113478809B discloses an additive manufacturing method of micro-nano structure, which controls the directional migration of charged dispersed phases in a gas based on an electric field effect, enabling the charged dispersed phases to stack on a substrate to form a desired micro-nano structure; the substrate is covered with a layer with opening pattern arrays, and the charged dispersed phases migrate through the hole channels in the layer with opening pattern arrays to reach the substrate during the migration, wherein the material of the layer with opening pattern arrays is a dielectric, and the dielectric is selected from the group consisting of silicon nitride, silicon oxide, and photoresist. This method can achieve low-cost, high-purity, multi-material, ultra-high resolution, ultra-fast, and one-time large-area printing of micro-nano structures, addressing challenges such as limited types of printable materials, low printing resolution, slow printing speed, and array printing at the micro-nanoscale. However, this method can only be performed on conductive substrates and cannot print on insulating substrates. Additionally, the printed patterns are formed by stacking nanoparticles, resulting in porosity, which leads to poor mechanical and electrical properties of the structures without post-processing. Furthermore, due to the effects of diffusion and charge repulsion, the patterns printed by this method exhibit unsharp edges and low sidewall verticality.

Therefore, developing a micro-nanoscale additive manufacturing method and a patterning method to overcome the aforementioned issues has become a crucial step.

### SUMMARY

The present disclosure aims to overcome the drawbacks of existing additive manufacturing methods for micro-nano structures based on the action of an electric field, which are not suitable for printing on insulating substrates and exhibit unsharp pattern edges and low sidewall verticality, and to provide a new micro-nanoscale additive manufacturing method and a patterning method. The micro-nanoscale additive manufacturing method of the present disclosure not only enables low cost, high throughput, high precision, small feature size, high density, low defects, simple operation, suitability for multi-material and multi-type pattern processing, but also enables printing on insulating substrates. The micro-nanoscale patterning method of the present disclosure can further make the manufactured patterns have sharp edges and high sidewall verticality.

The present disclosure provides the following technical solutions to address the above problems.

In one aspect, the present disclosure provides a micro-nanoscale additive manufacturing method, which guides directional migration of a charged phase dispersed in a gas by utilizing an electric field effect, allows the charged phase dispersed in the gas pass through a through-hole channel in a layer with opening pattern arrays on a substrate and then migrate and stack onto the substrate to form a printed structure, wherein the printed structure has a feature size smaller than that of the through-hole channel; wherein the substrate is an insulating substrate, and an electric field strength at a printing position is controlled to be not less than 15000 V/cm, wherein the direction of the electric field is either positive or negative.

The additive manufacturing method of the present disclosure forms a printed structure with a smaller feature size compared to an original layer with opening pattern arrays through the convergence of electric field lines. Specifically, by applying an external electric field and utilizing the local electric field formed on the surface of the layer with opening pattern arrays, as well as the counterbalancing effect between the two, a spatial electric field required for printing is constructed, causing the electric field lines to converge in the central region of the through-hole channel, such that the converged size is much smaller than the size of the through-hole channel, thereby obtaining a printed structure with significantly reduced feature size.

Herein, the electric field effect is generated by applying an external electric field, and the external electric field may have a strength of not less than 1 V/cm, preferably 1-10000 V/cm, wherein the direction of the electric field is either positive or negative.

In existing additive manufacturing methods for micro-nano structures based on electric field effect, a conductive substrate is required and the substrate is connected to an external circuit, so that the charges carried by the charged dispersed phase during the printing process need to be conducted away through the substrate; otherwise, repulsion between like charges will occur, making printing impossible. The inventors unexpectedly discovered during research that, when the substrate is an insulating substrate and is non-conductive, by merely controlling the electric field strength at the printing position to be not less than 15000 V/cm, wherein the direction of the electric field is either positive or negative, it is possible to cause corona discharge to occur in the printed structure during the printing process, thereby discharging the accumulated charges on the structure into the gas; additionally, the charges on the structure exhibit a polarization phenomenon under the action of the electric field, forcing the charges to be distributed to both ends of the structure, with the upper end capable of attracting oppositely charged nanoparticles, thereby successfully printing a structure.

Herein, the printing position refers to the position on the substrate where printing starts after electric field lines finally converge; the electric field lines start to converge when passing through the channel, and the convergence strength of the electric field lines remains unchanged until reaching the substrate. The electric field strength at the printing position is preferably 15000-30000 V/cm, for example, 20000 V/cm or 25000 V/cm, wherein the direction of the electric field is either positive or negative. The electric field strength at the printing position is achieved by adjusting the external electric field strength to the desired strength.

Herein, the insulating substrate may be various types of insulating substrate suitable for the field of micro-nano fabrication, preferably a silicon dioxide substrate, a glass substrate, or a plastic substrate.

Herein, the gas is a multiphase fluid in which a gaseous phase serves as a continuous phase and a solid and/or liquid phase serves as a dispersed phase. The gas may be any suitable carrier gas, such as one or more of nitrogen, inert gas, oxygen, hydrogen, sulfur hexafluoride, uranium hexafluoride, tungsten hexafluoride, and chlorine. The gas is preferably used in an amount of 0.1-100 L/min.

Herein, the charged phase dispersed in the gas is a charged liquid and/or solid substance dispersed in the gas, and the material of the charged phase dispersed in the gas is various types of materials suitable for printing in the art, which may be one or more selected from the group consisting of inorganic materials, organic materials, and composite materials, preferably conductor materials or semiconductor materials. The conductor material is preferably a metallic material, such as an elemental metal or an alloy. The metallic element in the metallic material is one or more selected from the group consisting of magnesium, aluminum, titanium, vanadium, chromium, manganese, iron, cobalt, nickel, copper, zinc, gallium, germanium, yttrium, zirconium, niobium, molybdenum, technetium, ruthenium, rhodium, palladium, silver, cadmium, indium, tin, antimony, hafnium, tantalum, tungsten, rhenium, iridium, platinum, gold, lead, and bismuth. The conductor material may also be a non-metallic element in its elemental form, or a compound formed from a non-metallic element in its elemental form and a metal. The non-metallic element may be one or more selected from the group consisting of boron, carbon, nitrogen, oxygen, silicon, and arsenic. The organic material is preferably a polymer material or a biomolecular material. The size of the charged phase dispersed in the gas is preferably from 0.1 nm to 10 μm.

The charged phase dispersed in the gas may be prepared by a discharge plasma technology, a gas atomization method, or an electrospray method. When the material of the printed structure is conductive or semiconductive, such as a metallic material or a semiconductor material, the charged phase dispersed in the gas may be prepared by the discharge plasma technology. When the material of the dispersed phase is a solution, the charged phase dispersed in the gas may be prepared by the gas atomization method or the electrospray method.

Herein, the layer with opening pattern arrays may be various conventional layer with opening pattern arrayss in the art, such as a mask with opening pattern arrays, or a layer with opening pattern arrays fabricated according to conventional methods, for example, by photolithography. The material of the layer with opening pattern arrays may be a dielectric, such as silicon nitride, silicon oxide, or photoresist; it may also be a conductive layer, such as a metallic material.

The spacing between the layer with opening pattern arrays and the substrate is greater than or equal to 0, typically ranging from 0 to 50 micrometers. The case where the spacing is greater than 0 indicates that the layer with opening pattern arrays is separated from the substrate, for example, a mask with opening pattern arrays may be suspended above the substrate. When the spacing is equal to 0, the layer with opening pattern arrays is in contact with the substrate.

Optionally, by adjusting the distance between the layer with opening pattern arrays and the substrate, the electric potential of the layer with opening pattern arrays may be controlled to regulate the distribution of the spatial electric field, thereby controlling the shape and size of the printed structure.

The opening pattern and the pattern of the printed structure may be various simple patterns or complex patterns. The simple patterns may be dots, straight lines, or circular arcs. The complex patterns may be intersecting lines, zigzag lines, dot arrays, square arrays, polygons, or a combined pattern of one or more of the foregoing patterns and the simple patterns. The feature size of the opening pattern is preferably a factor of 1 to 100, more preferably 1 to 20, still more preferably 2 to 20, for example, 4, 5, 6, 10, or 16 to the feature size of the printed structure. The feature size of the printed structure may be 0.1 nm to 10 μm, preferably 0.1 nm to 1000 nm, for example, 1000 nm, 800 nm, 400 nm, 300 nm, or 200 nm.

On the other hand, the present disclosure provides a micro-nanoscale patterning method, comprising: transferring a printed structure formed on a substrate into the substrate; wherein the printed structure is produced by the following additive manufacturing method: guiding directional migration of a charged phase dispersed in a gas by utilizing an electric field effect, and allowing the charged phase dispersed in the gas pass through a through-hole channel in a layer with opening pattern arrays and then migrate and stack onto the substrate to form a printed structure, wherein the printed structure has a feature size smaller than that of the through-hole channel; the substrate is a conductive substrate or an insulating substrate; when the substrate is a conductive substrate, the substrate is connected to an external circuit; when the substrate is an insulating substrate, an electric field strength at a printing position is controlled to be not less than 15000 V/cm, wherein the direction of the electric field is either positive or negative; wherein the transferring is performed in any one of the following methods:
(1) on a substrate formed with the printed structure only, etching the part of the substrate that is not covered with the printed structure, and then removing the printed structure from the substrate; and
(2) on a substrate covered with the layer with opening pattern arrays and formed with the printed structure, etching the part of the substrate that is not covered with the printed structure and is not covered with the layer with opening pattern arrays, and then removing the layer with opening pattern arrays and the printed structure from the substrate.

Herein, the conductive substrate is preferably a silicon substrate, a silicon nitride substrate, or a silicon carbide substrate, and more preferably a silicon substrate. The insulating substrate is preferably a silicon dioxide substrate, a glass substrate, or a plastic substrate.

When the substrate is an insulating substrate, the electric field strength at the printing position is preferably 15000-30000 V/cm, wherein the direction of the electric field is either positive or negative.

Except for the types of substrates and the electric field strength at the printing position as described above, the specific steps and other conditions of the additive manufacturing method are as described in the first aspect.

In method (1) of the transferring, before the etching, a step of removing the layer with opening pattern arrays may further be included, so as to prepare the substrate having only the printed structure. In method (2) of the transferring, the layer with opening pattern arrays is preferably removed first, and then the printed structure is removed.

Herein, the etching may be selective etching or non-selective etching, preferably reactive ion beam selective etching. Specific etching methods and conditions may be selected according to the convention in the art. The ratio of the depth of the etching to the feature size of the printed structure is preferably 1-10, more preferably 1-4, for example, 1, 2, or 4.

Herein, removing the layer with opening pattern arrays may be selected according to conventional methods and conditions in the art based on the material of the layer with opening pattern arrays. For example, when the material of the layer with opening pattern arrays is photoresist, the layer with opening pattern arrays is removed by plasma bombardment or solvent dissolution; and when the layer with opening pattern arrays is a mask, the mask is moved away from the substrate having the printed structure by a nanoscale translation stage.

Herein, removing the printed structure may be selected according to conventional methods and conditions in the art based on the material of the printed structure. For example, when the material of the printed structure is a metal, the printed structure is removed using a metal etchant. Specifically, when the material of the printed structure is gold, the printed structure is removed using a potassium iodide solution.

Herein, before the transferring, a step of obtaining the printed structure using the additive manufacturing method as mentioned above may further be included.

The patterning method of the present disclosure may form a pattern with an area of not less than 8 mm² in a single operation.

Based on common knowledge in the art, the aforementioned preferred conditions can be combined arbitrarily to obtain various preferred embodiments of the present disclosure.

The positive and progressive effects of the present disclosure are as follows:
(1) The micro-nanoscale additive manufacturing method of the present disclosure enables printing structures on an insulating substrate merely by controlling the electric field strength at the printing location.
(2) The micro-nanoscale patterning method of the present disclosure can construct patterns with high etch resistance, achieving significant reduction in feature size and multiplication of pattern density, while also enabling that the fabricated patterns have sharp edges and high sidewall verticality.
(3) The method of the present disclosure exhibits low cost, high precision, high throughput, few defects, simple operation, and convenient processing. It is suitable for multi-material and multi-type pattern processing, can achieve large-area patterning in a single step, and offers the advantages of high speed and efficiency.

### BRIEF DESCRIPTION OF THE DRAWINGS

FIGS. 1A-1B respectively show schematic diagrams of electric field line convergence in the additive manufacturing method according to Examples 1-12 and 13-14 of the present disclosure; FIG. 1C shows a schematic flowchart of the pattern transfer method according to the present disclosure, wherein Method 1 corresponds to Examples 1-5 and 13-14, and Method 2 corresponds to Examples 6-12.

FIGS. 2A-2D show SEM images of a sample after patterning with a straight-line pattern according to Example 1 of the present disclosure.

FIGS. 3A-3D show SEM images of a sample after patterning with a circular arc pattern according to Example 2 of the present disclosure.

FIG. 4 shows an SEM image of a sample after patterning with a combined pattern of a circular arc and a straight line according to Example 3 of the present disclosure.

FIGS. 5A-5D show SEM images of a sample after patterning with a zigzag pattern according to Example 4 of the present disclosure.

FIGS. 6A-6B show SEM images of a sample after patterning with a grid-line pattern according to Example 5 of the present disclosure.

FIGS. 7A-7B show SEM images of a sample after patterning with a circular dot array pattern according to Example 6 of the present disclosure.

FIGS. 8A-8D show SEM images of a sample after patterning with a square dot array pattern according to Example 7 of the present disclosure.

FIGS. 9A-9D show SEM images of a sample after patterning with a circular arc pattern according to Example 8 of the present disclosure.

FIGS. 10A-10D show SEM images of a sample after patterning with a zigzag pattern according to Example 9 of the present disclosure.

FIGS. 11A-11C show SEM images of a sample after patterning with a triangular outline pattern according to Example 10 of the present disclosure.

FIGS. 12A-12C show SEM images of a sample after patterning with a grid-line pattern according to Example 11 of the present disclosure.

FIGS. 13A-13B show SEM images of a sample after patterning with a combined pattern of a circular arc and a straight line according to Example 12 of the present disclosure.

FIGS. 14A-14D show SEM images of a pattern printed and the pattern after transfer according to the method in Example 8 of the present disclosure.

FIGS. 15A-15B show SEM images of the patterns printed according to the additive manufacturing method in Example 1 of the present disclosure; FIGS. 15C-15D show SEM images of the patterns after transfer according to the patterning methods in Examples 8 and 10, respectively.

FIGS. 16A-16B show SEM images of a printed structure according to Example 13 of the present disclosure.

FIGS. 17A-17B show SEM images of a printed structure according to Example 14 of the present disclosure.

### DETAILED DESCRIPTION OF THE PREFERRED EMBODIMENT

The specific embodiments of the present disclosure are described below. However, those skilled in the art should understand that these are merely illustrative examples, and various changes or modifications can be made to these embodiments without departing from the principles and essence of the present disclosure. Therefore, the scope of protection of the present disclosure is defined by the appended claims. Meanwhile, the accompanying drawings are merely schematic illustrations of the present disclosure and are not intended to limit the scope of the present disclosure.

### Example 1

(1) AZ 5214 photoresist with a thickness of 1.5 μm was spin-coated onto a silicon substrate at a rotational speed of 4000 r/min for 30 s;

(2) A straight-line pattern with a feature size (line width) of 2 μm was exposed, followed by development for 45 s to remove the photoresist in the exposed areas;

(3) The silicon substrate was connected to an external circuit, and a printing process was carried out for 1 hour using a charged Au dispersed phase with a concentration of 1.5×10⁷ particles/cm³ and an average size of 5 nm, under a nitrogen atmosphere (purity: 99.999%) with a gas flow rate of 3 L/min and an external electric field strength of 200 V/cm, so as to print and stack onto the straight-line pattern with a feature size of 2 μm, thereby forming a straight-line structure with a feature size (line width) of 200 nm;

(4) The photoresist on the surface of the substrate was removed by oxygen plasma bombardment using a plasma cleaner operated at a power of 50 W for 20 min;

(5) The substrate was selectively etched using a reactive ion beam to a depth of 800 nm;

(6) The sample was immersed in a KI metal etchant with a concentration of 5 wt % for 5 min. After removing the printed structure, a sample patterned with the straight-line pattern was obtained.

### Example 2

(1) AZ 5214 photoresist with a thickness of 1.5 μm was spin-coated onto a silicon substrate at a rotational speed of 4000 r/min for 30 s;

(2) A circular arc pattern with a feature size of 2μm was exposed, wherein the inner diameter of the circular arc was 12 μm and the outer diameter was 14 μm, followed by development for 45 s to remove the photoresist in the exposed area;

(3) The silicon substrate was connected to an external circuit, and a printing process was carried out for 1 hour using a charged Au dispersed phase with a concentration of 1.5 ×10⁷ particles/cm³ and an average size of 5 nm, under a nitrogen atmosphere (purity: 99.999%) with a gas flow rate of 3 L/min and an external electric field strength of 200 V/cm, so as to print and stack onto the circular arc pattern with a feature size of 2 μm, thereby forming a circular arc structure with a feature size of 200 nm;

(4) The photoresist on the surface of the substrate was removed by oxygen plasma bombardment using a plasma cleaner operated at a power of 50 W for 20 min;

(5) The substrate was selectively etched using a reactive ion beam to a depth of 800 nm;

(6) The sample was immersed in a KI metal etchant with a concentration of 5 wt % for 5 min. After removing the printed structure, a sample patterned with the circular arc pattern was obtained.

### Example 3

(1) AZ 5214 photoresist with a thickness of 1.5 μm was spin-coated onto a silicon substrate at a rotational speed of 4000 r/min for 30 s;

(2) A combined pattern of a circular arc and a straight line with a feature size of 2 μm was exposed, wherein the inner diameter of the circular arc was 12 μm and the outer diameter was 14 μm, followed by development for 45 s to remove the photoresist in the exposed area;

(3) The silicon substrate was connected to an external circuit, and a printing process was carried out for 1 hour using a charged Au dispersed phase with a concentration of 1.5×10⁷ particles/cm³ and an average size of 5 nm, under a nitrogen atmosphere (purity: 99.999%) with a gas flow rate of 3 L/min and an external electric field strength of 200 V/cm, so as to print and stack onto the combined pattern of a circular arc and a straight line with a feature size of 2 μm, thereby forming a combined structure of a circular arc and a straight line with a feature size of 200 nm;

(4) The photoresist on the surface of the substrate was removed by oxygen plasma bombardment using a plasma cleaner operated at a power of 50 W for 20 min;

(5) The substrate was selectively etched using a reactive ion beam to a depth of 800 nm;

(6) The sample was immersed in a KI metal etchant with a concentration of 5 wt % for 5 min. After removing the printed structure, a sample patterned with the combined pattern of a circular arc and a straight line was obtained.

### Example 4

(1) AZ 5214 photoresist with a thickness of 1.5 μm was spin-coated onto a silicon substrate at a rotational speed of 4000 r/min for 30 s;

(2) A zigzag pattern with a feature size (line width) of 2 μm was exposed, followed by development for 45 s to remove the photoresist in the exposed areas;

(3) The silicon substrate was connected to an external circuit, and a printing process was carried out for 1 hour using a charged Au dispersed phase with a concentration of 1.5×10⁷ particles/cm³ and an average size of 5 nm, under a nitrogen atmosphere (purity: 99.999%) with a gas flow rate of 3 L/min and an external electric field strength of 200 V/cm, so as to print and stack onto the zigzag pattern with a feature size of 2 μm, thereby forming a zigzag structure with a feature size of 200 nm;

(4) The photoresist on the surface of the substrate was removed by oxygen plasma bombardment using a plasma cleaner operated at a power of 50 W for 20 min;

(5) The substrate was selectively etched using a reactive ion beam to a depth of 800 nm;

(6) The sample was immersed in a KI metal etchant with a concentration of 5 wt % for 5 min. After removing the printed structure, a sample patterned with the zigzag pattern was obtained.

### Example 5

(1) AZ 5214 photoresist with a thickness of 1.5 μm was spin-coated onto a silicon substrate at a rotational speed of 4000 r/min for 30 s;

(2) A grid-line pattern with a feature size (line width) of 2 μm was exposed, followed by development for 45 s to remove the photoresist in the exposed areas;

(3) The silicon substrate was connected to an external circuit, and a printing process was carried out for 1 hour using a charged Au dispersed phase with a concentration of 1.5×10⁷ particles/cm³ and an average size of 5 nm, under a nitrogen atmosphere (purity: 99.999%) with a gas flow rate of 3 L/min and an external electric field strength of 200 V/cm, so as to print and stack onto the grid-line pattern with a feature size of 2 μm, thereby forming a grid-line structure with a feature size of 200 nm;

(4) The photoresist on the surface of the substrate was removed by oxygen plasma bombardment using a plasma cleaner operated at a power of 50 W for 20 min;

(5) The substrate was selectively etched using a reactive ion beam to a depth of 800 nm;

(6) The sample was immersed in a KI metal etchant with a concentration of 5 wt % for 5 min. After removing the printed structure, a sample patterned with the grid-line pattern was obtained.

### Example 6

(1) AZ 5214 photoresist with a thickness of 1.5 μm was spin-coated onto a silicon substrate at a rotational speed of 4000 r/min for 30 s;

(2) A circular dot array pattern with a feature size of 2.5 μm was exposed, followed by development for 45 s to remove the photoresist in the exposed areas, wherein the silicon substrate was connected to an external circuit;

(3) The silicon substrate was connected to an external circuit, and a printing process was carried out for 1 hour using a charged Au dispersed phase with a concentration of 1.5×10⁷ particles/cm³ and an average size of 5 nm, under a nitrogen atmosphere (purity: 99.999%) with a gas flow rate of 3 L/min and an external electric field strength of 200 V/cm, so as to print and stack onto the circular dot array pattern with a feature size of 2.5 μm to form a circular dot structure with a feature size of 400 nm;

(4) The substrate was selectively etched using a reactive ion beam to a depth of 500 nm;

(5) The photoresist on the surface of the substrate was removed by oxygen plasma bombardment using a plasma cleaner operated at a power of 50 W for 20 min;

(6) The sample was immersed in a KI metal etchant with a concentration of 5 wt % for 5 min. After removing the printed structure, a sample patterned with the circular dot array pattern was obtained.

### Example 7

(1) AZ 5214 photoresist with a thickness of 1.5 μm was spin-coated onto a silicon substrate at a rotational speed of 4000 r/min for 30 s;

(2) A square dot array pattern with feature sizes of 4.5 μm and 2 μm was exposed, followed by development for 45 s to remove the photoresist in the exposed areas;

(3) The silicon substrate was connected to an external circuit, and a printing process was carried out for 1 hour using a charged Au dispersed phase with a concentration of 1.5×10⁷ particles/cm³ and an average size of 5 nm, under a nitrogen atmosphere (purity: 99.999%) with a gas flow rate of 3 L/min and an external electric field strength of 200 V/cm, so as to print and stack onto the square dot array patterns with feature sizes of 4.5 μm and 2 μm, respectively, thereby forming square dot structures with feature sizes of 1 μm and 400 nm, respectively;

(4) The substrate was selectively etched using a reactive ion beam to a depth of 500 nm;

(5) The photoresist on the surface of the substrate was removed by oxygen plasma bombardment using a plasma cleaner operated at a power of 50 W for 20 min;

(6) The sample was immersed in a KI metal etchant with a concentration of 5 wt % for 5 min. After removing the printed structure, a sample patterned with the square dot array patterns was obtained.

### Example 8

(1) AZ 5214 photoresist with a thickness of 1.5 μm was spin-coated onto a silicon substrate at a rotational speed of 4000 r/min for 30 s;

(2) A circular arc pattern with a feature size of 2 μm was exposed, wherein the inner diameter of the circular arc was 12 μm and the outer diameter was 14 μm, followed by development for 45 s to remove the photoresist in the exposed area;

(3) The silicon substrate was connected to an external circuit, and a printing process was carried out for 1 hour using a charged Au dispersed phase with a concentration of 1.5×10⁷ particles/cm³ and an average size of 5 nm, under a nitrogen atmosphere (purity: 99.999%) with a gas flow rate of 3 L/min and an external electric field strength of 200 V/cm, so as to print and stack onto the circular arc pattern with a feature size of 2 μm, thereby forming a circular arc structure with a feature size of 200 nm;

(4) The substrate was selectively etched using a reactive ion beam to a depth of 400 nm;

(5) The photoresist on the surface of the substrate was removed by oxygen plasma bombardment using a plasma cleaner operated at a power of 50 W for 20 min;

(6) The sample was immersed in a KI metal etchant with a concentration of 5 wt % for 5 min. After removing the printed structure, a sample patterned with the circular arc pattern was obtained.

### Example 9

(1) AZ 5214 photoresist with a thickness of 1.5 μm was spin-coated onto a silicon substrate at a rotational speed of 4000 r/min for 30 s;

(2) A zigzag pattern with a feature size of 2 μm was exposed, followed by development for 45 s to remove the photoresist in the exposed areas;

(3) The silicon substrate was connected to an external circuit, and a printing process was carried out for 1 hour using a charged Au dispersed phase with a concentration of 1.5×10⁷ particles/cm³ and an average size of 5 nm, under a nitrogen atmosphere (purity: 99.999%) with a gas flow rate of 3 L/min and an external electric field strength of 200 V/cm, so as to print and stack onto the zigzag pattern with a feature size of 2 μm, thereby forming a zigzag structure with a feature size of 200 nm;

(4) The substrate was selectively etched using a reactive ion beam to a depth of 400 nm;

(5) The photoresist on the surface of the substrate was removed by oxygen plasma bombardment using a plasma cleaner operated at a power of 50 W for 20 min;

(6) The sample was immersed in a KI metal etchant with a concentration of 5 wt % for 5 min. After removing the printed structure, a sample patterned with the zigzag pattern was obtained.

### Example 10

(1) AZ 5214 photoresist with a thickness of 1.5 μm was spin-coated onto a silicon substrate at a rotational speed of 4000 r/min for 30 s;

(2) A triangular outline pattern with a feature size of 2 μm was exposed, followed by development for 45 s to remove the photoresist in the exposed areas;

(3) The silicon substrate was connected to an external circuit, and a printing process was carried out for 1 hour using a charged Au dispersed phase with a concentration of 1.5×10⁷ particles/cm³ and an average size of 5 nm, under a nitrogen atmosphere (purity: 99.999%) with a gas flow rate of 3 L/min and an external electric field strength of 200 V/cm, so as to print and stack onto the triangular outline pattern with a feature size of 2 μm, thereby forming a triangular outline structure with a feature size of 200 nm;

(4) The substrate was selectively etched using a reactive ion beam to a depth of 400 nm;

(5) The photoresist on the surface of the substrate was removed by oxygen plasma bombardment using a plasma cleaner operated at a power of 50 W for 20 min;

(6) The sample was immersed in a KI metal etchant with a concentration of 5 wt % for 5 min. After removing the printed structure, a sample patterned with the triangular outline pattern was obtained.

### Example 11

(1) AZ 5214 photoresist with a thickness of 1.5 μm was spin-coated onto a silicon substrate at a rotational speed of 4000 r/min for 30 s;

(2) A grid-line pattern with a feature size of 2 μm was exposed, followed by development for 45 s to remove the photoresist in the exposed areas;

(3) The silicon substrate was connected to an external circuit, and a printing process was carried out for 1 hour using a charged Au dispersed phase with a concentration of 1.5×10⁷ particles/cm³ and an average size of 5 nm, under a nitrogen atmosphere (purity: 99.999%) with a gas flow rate of 3 L/min and an external electric field strength of 200 V/cm, so as to print and stack onto the grid-line pattern with a feature size of 2 μm, thereby forming a grid-line structure with a feature size of 200 nm;

(4) The substrate was selectively etched using a reactive ion beam to a depth of 400 nm;

(5) The photoresist on the surface of the substrate was removed by oxygen plasma bombardment using a plasma cleaner operated at a power of 50 W for 20 min;

(6) The sample was immersed in a KI metal etchant with a concentration of 5 wt % for 5 min. After removing the printed structure, a sample patterned with the grid-line pattern was obtained.

### Example 12

(1) AZ 5214 photoresist with a thickness of 1.5 μm was spin-coated onto a silicon substrate at a rotational speed of 4000 r/min for 30 s;

(2) A combined pattern of a circular arc and a straight line with a feature size of 2 μm was exposed, wherein the inner diameter of the circular arc was 12 μm and the outer diameter was 14μm, followed by development for 45 s to remove the photoresist in the exposed area;

(3) The silicon substrate was connected to an external circuit, and a printing process was carried out for 1 hour using a charged Au dispersed phase with a concentration of 1.5×10⁷ particles/cm³ and an average size of 5 nm, under a nitrogen atmosphere (purity: 99.999%) with a gas flow rate of 3 L/min and an external electric field strength of 200 V/cm, so as to print and stack onto the combined pattern of a circular arc and a straight line with a feature size of 2 μm, thereby forming a combined structure of a circular arc and a straight line with a feature size of 200 nm;

(4) The substrate was selectively etched using a reactive ion beam to a depth of 400 nm;

(5) The photoresist on the surface of the substrate was removed by oxygen plasma bombardment using a plasma cleaner operated at 50 W for 20 min;

(6) The sample was immersed in a KI metal etchant with a concentration of 5 wt % for 5 min. After removing the printed structure, a sample patterned with the combined pattern of a circular arc and a straight line was obtained.

### Example 13

(1) A suspended mask was placed 5 μm above the silica insulating substrate as a layer with opening pattern arrays, in which circular holes with a diameter of 5 μm and a spacing of 10 μm were distributed on the suspended mask;

(2) Using a Pt dispersed phase with a concentration of 5.5×10⁷ particles/cm³ and an average size of 3 nm, a printing process was carried out for 1 hour under a nitrogen atmosphere (purity: 99.999%) with a gas flow rate of 5 L/min and an external electric field strength of 2000 V/cm. The electric field strength at the printing position was controlled to 20000 V/cm to print structures with a diameter of 300 nm. After printing, the suspended mask was moved away from the substrate using a nanoscale translation stage;

(3) The substrate was selectively etched using a reactive ion beam to a depth of 400 nm;

(4) The sample was immersed in an 85 wt % phosphoric acid metal etchant for 5 min. After removing the printed structure, a sample patterned with dot patterns was obtained.

### Example 14

(1) A suspended mask was placed 2 μm above the silica insulating substrate as a layer with opening pattern arrays, in which line-shaped holes with a length of 6 μm, a width of 3 μm, and a spacing of 12 μm were distributed on the suspended mask;

(2) Using a Pt dispersed phase with a concentration of 5.5×10⁷ particles/cm³ and an average size of 3 nm, the printing process was carried out for 1 hour under a nitrogen atmosphere (purity: 99.999%) with a gas flow rate of 5 L/min and an external electric field strength E1 of 1000 V/cm. The electric field strength at the printing position was controlled to 15000 V/cm to print structures with a line width of 800 nm. After printing, the suspended mask was moved away from the substrate using a nanoscale translation stage.

(3) The substrate was selectively etched using a reactive ion beam to a depth of 400 nm;

(4) The sample was immersed in an 85 wt % phosphoric acid metal etchant for 5 min. After removing the printed structure, a sample patterned with straight-line patterns was obtained.

### Effect Example

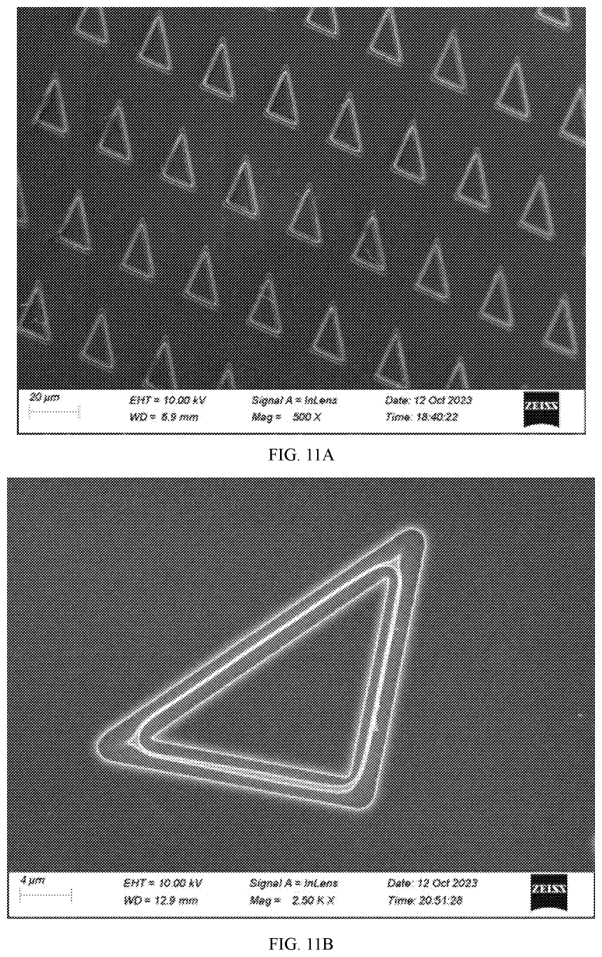

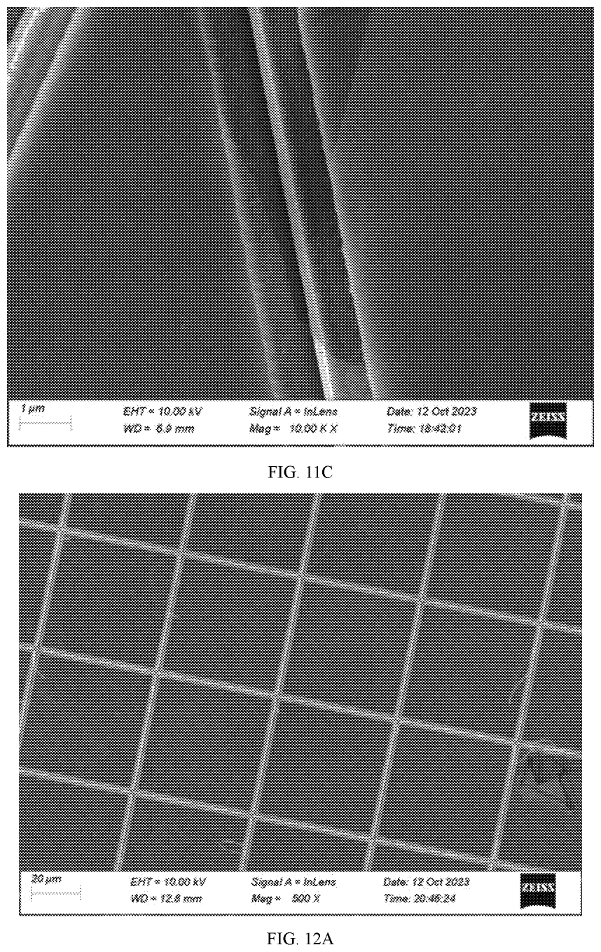

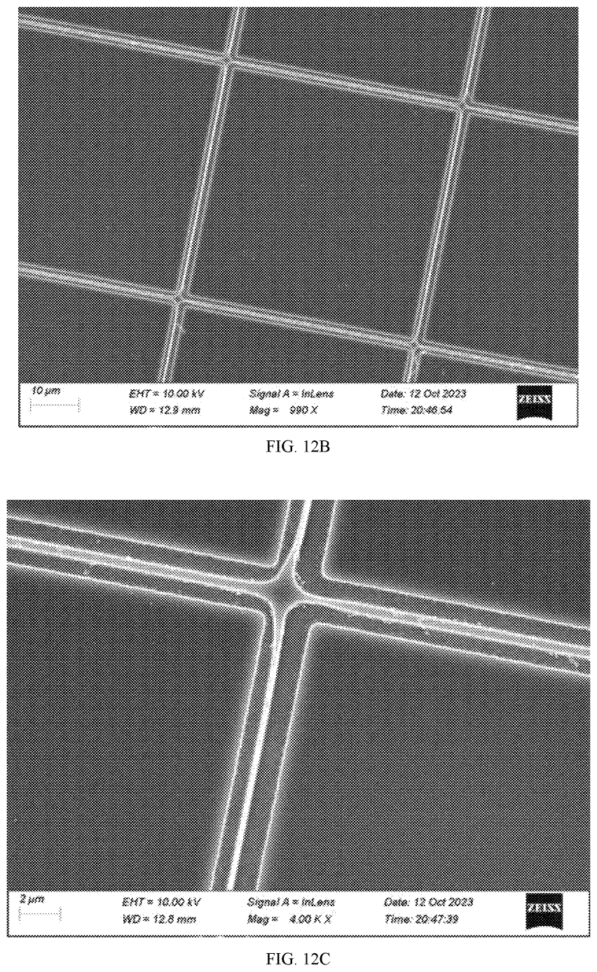

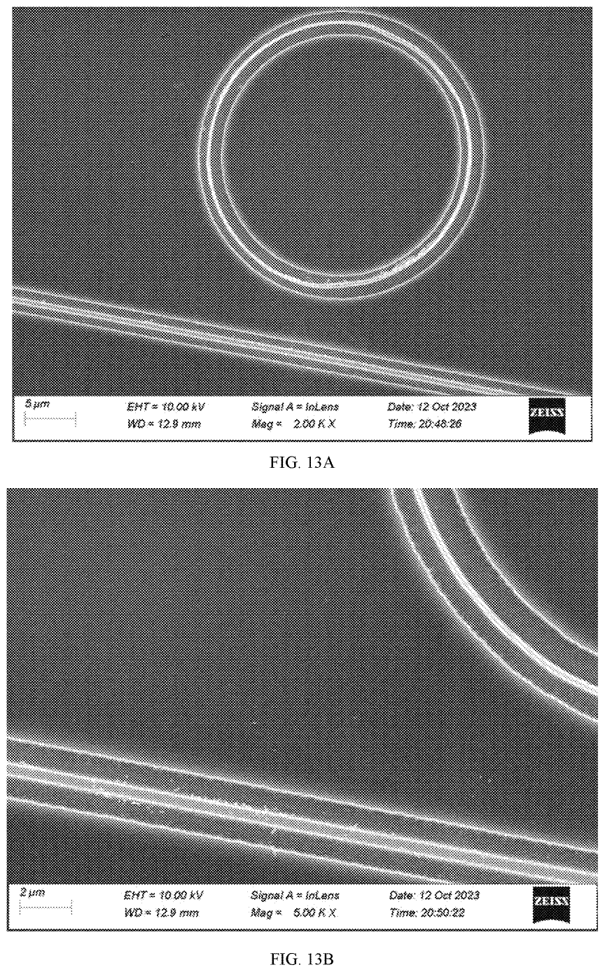

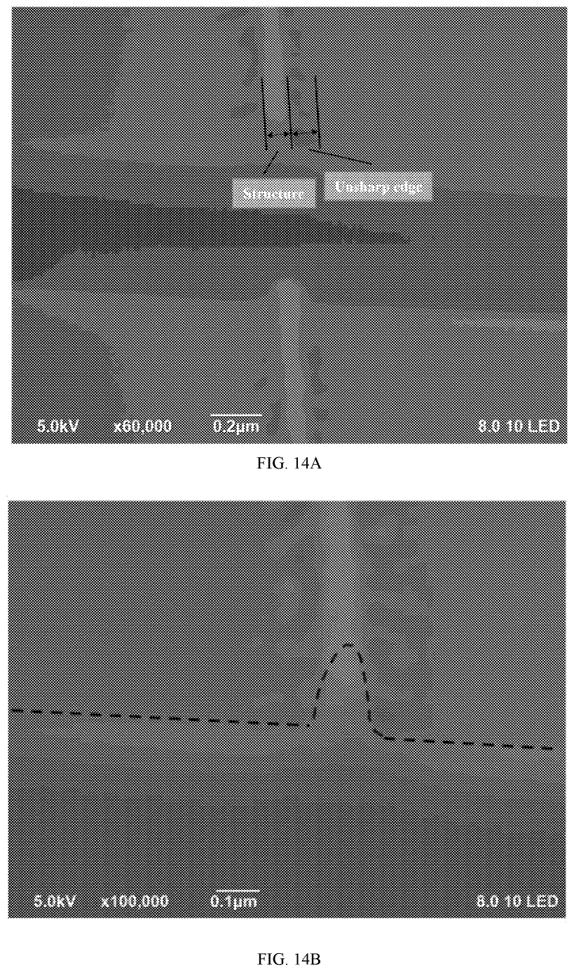

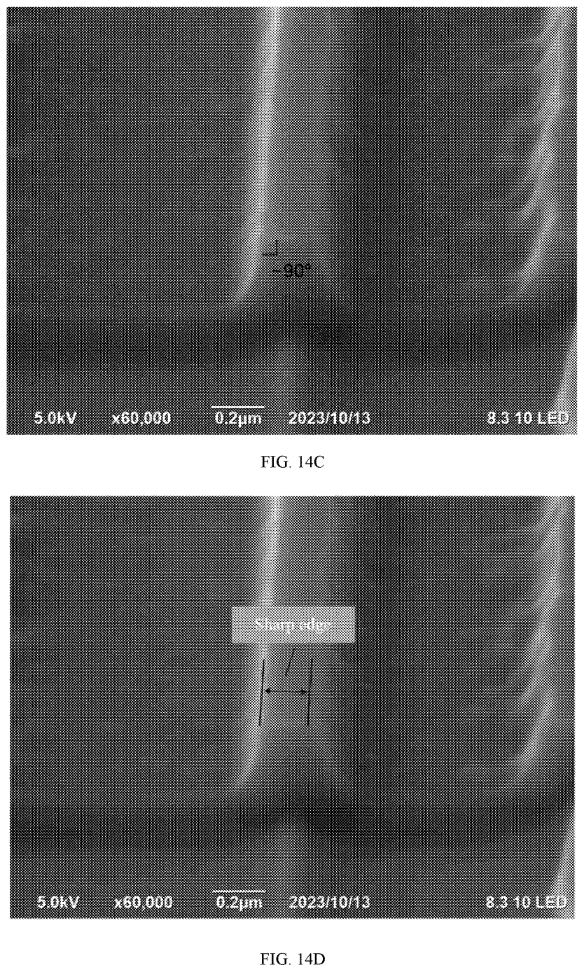

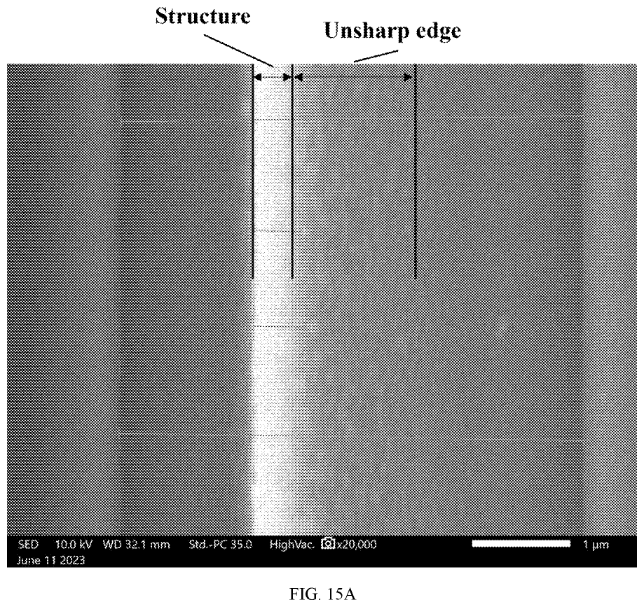

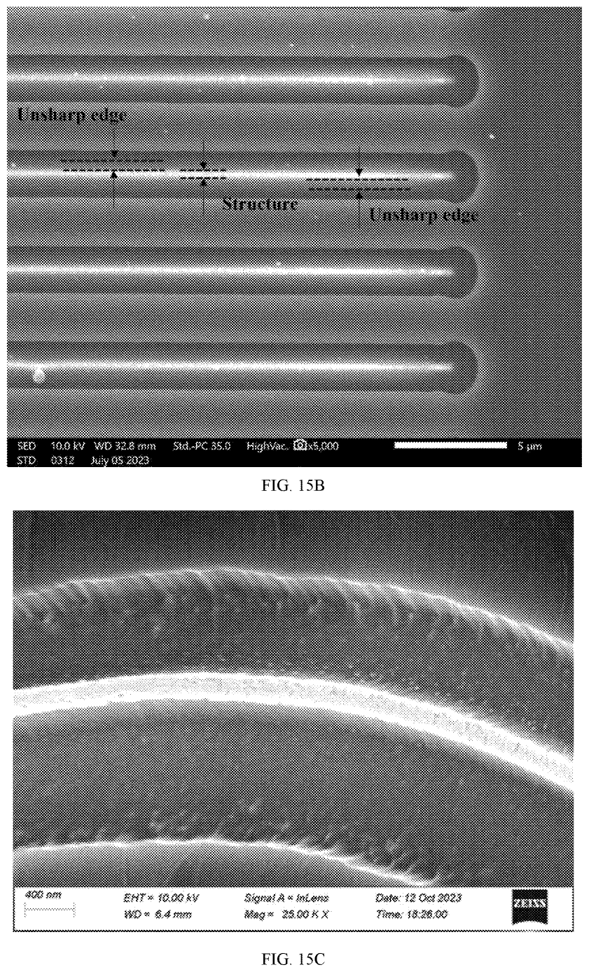

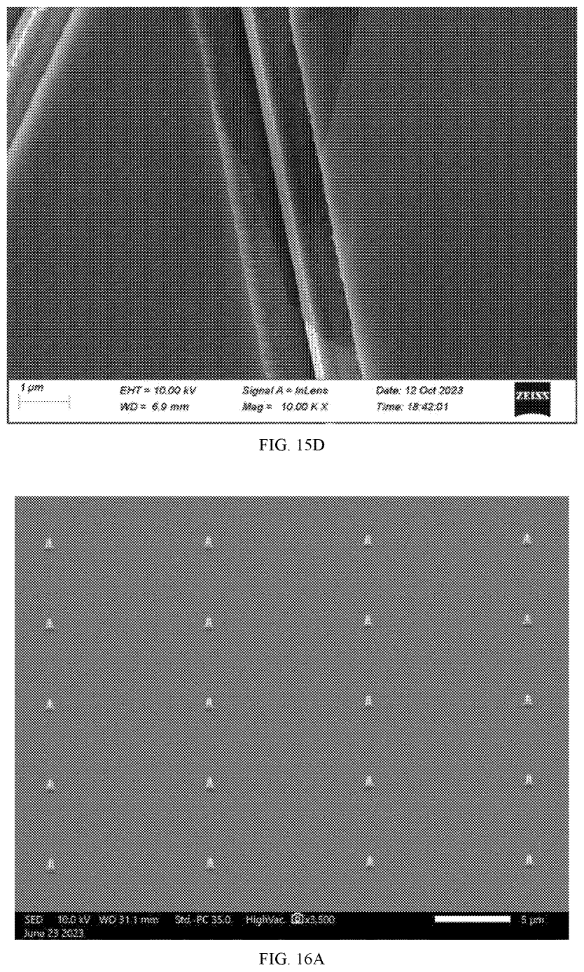

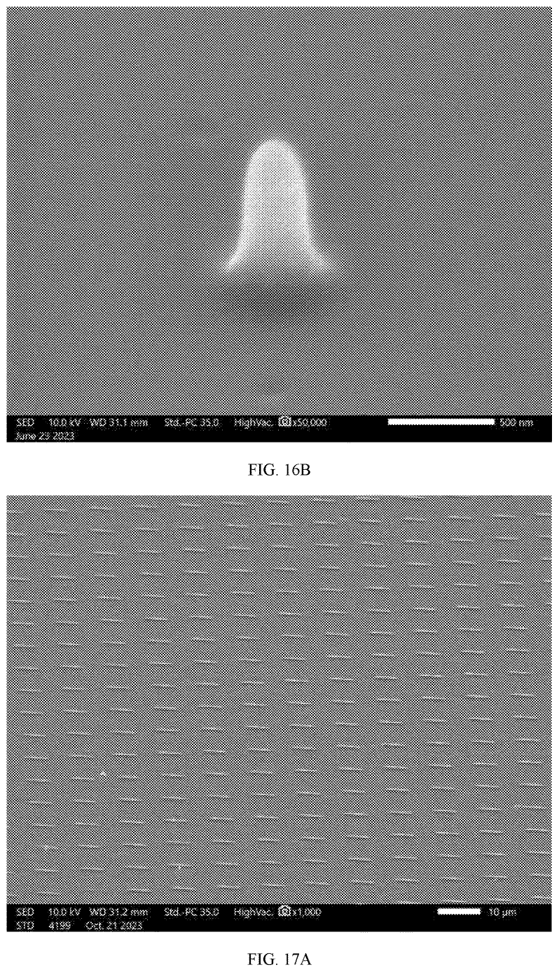

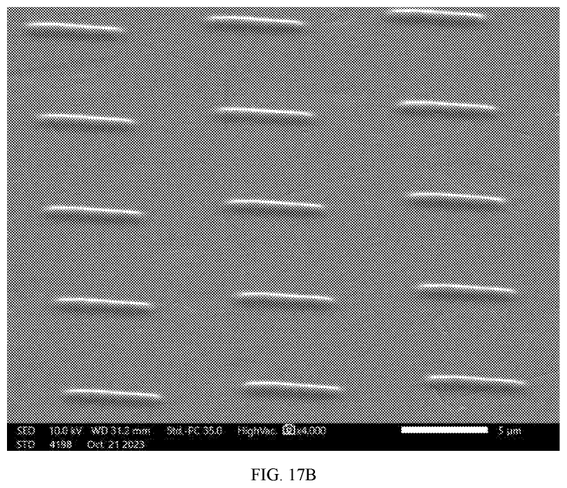

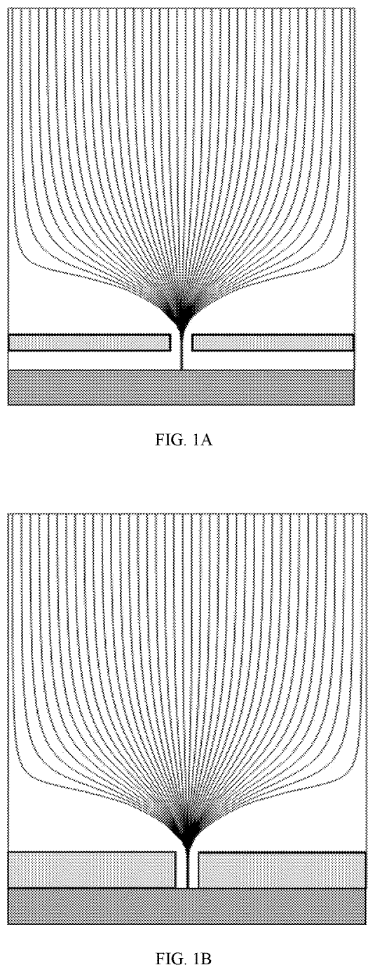

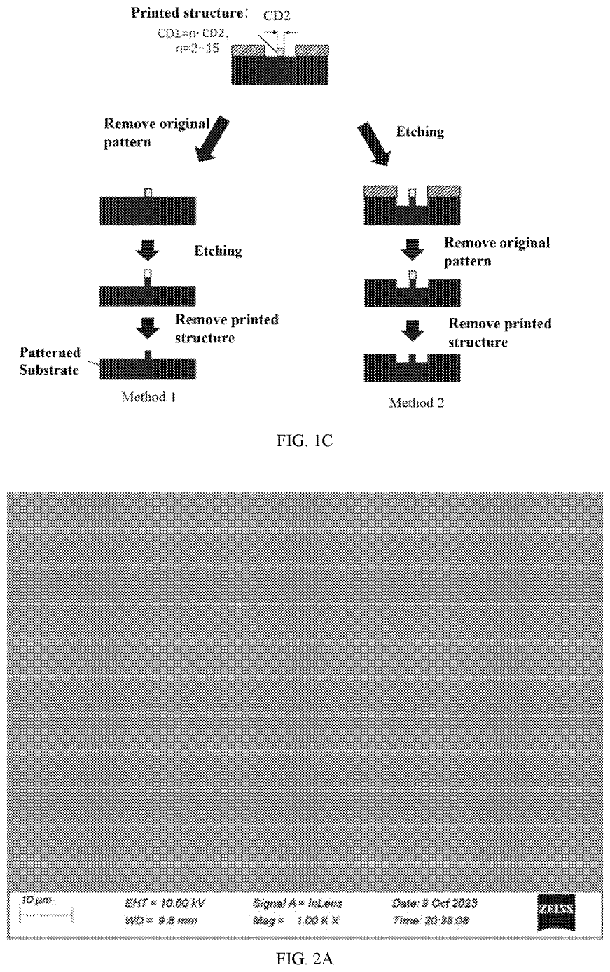

FIG. 1A and FIG. 1B are schematic diagrams illustrating the electric field line convergence for the additive manufacturing methods (steps (1)-(3)) according to Examples 1-12 and for the additive manufacturing methods (steps (1)-(2)) according to Examples 13-14, respectively.

FIG. 1C is a schematic flowchart of the pattern transfer method according to Examples 1-14, wherein Method 1 corresponds to Examples 1-5 and Examples 13-14, and Method 2 corresponds to Examples 6-12.

The samples obtained according to the aforementioned examples were observed under different magnifications using a scanning electron microscope (SEM).

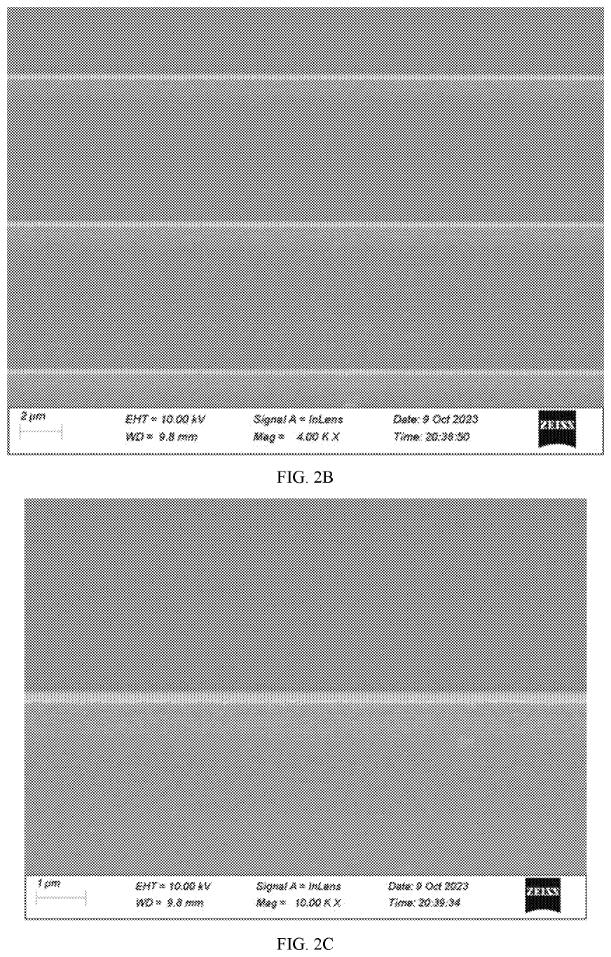

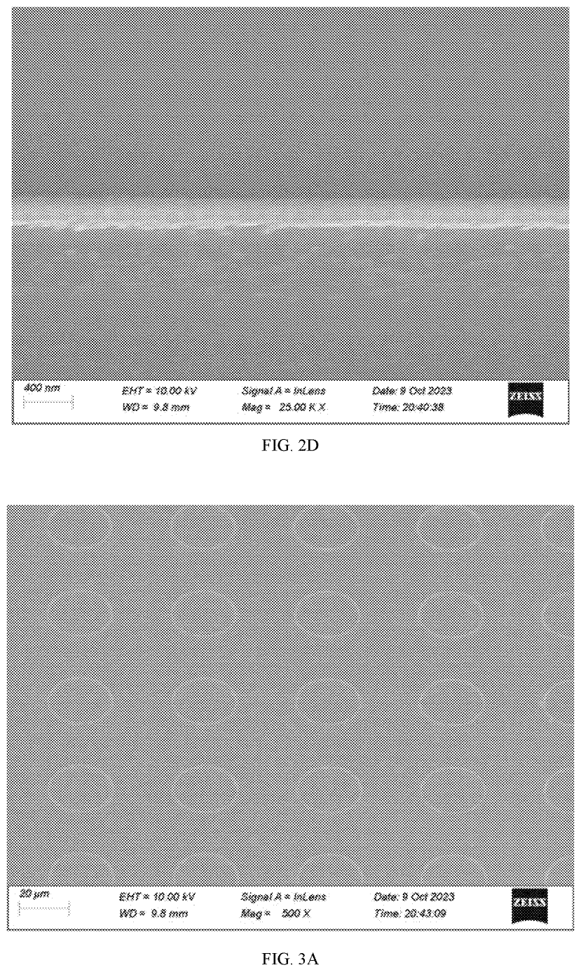

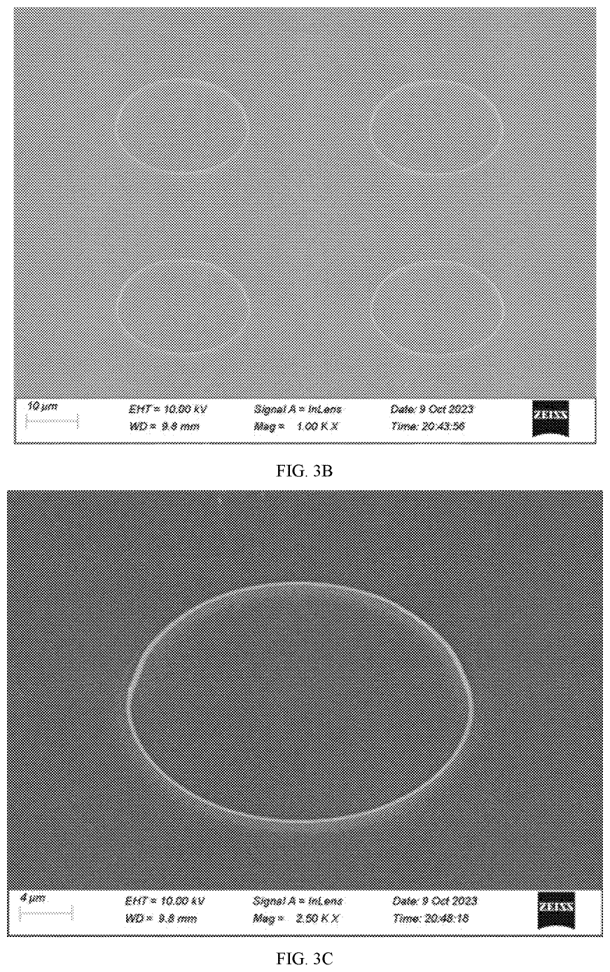

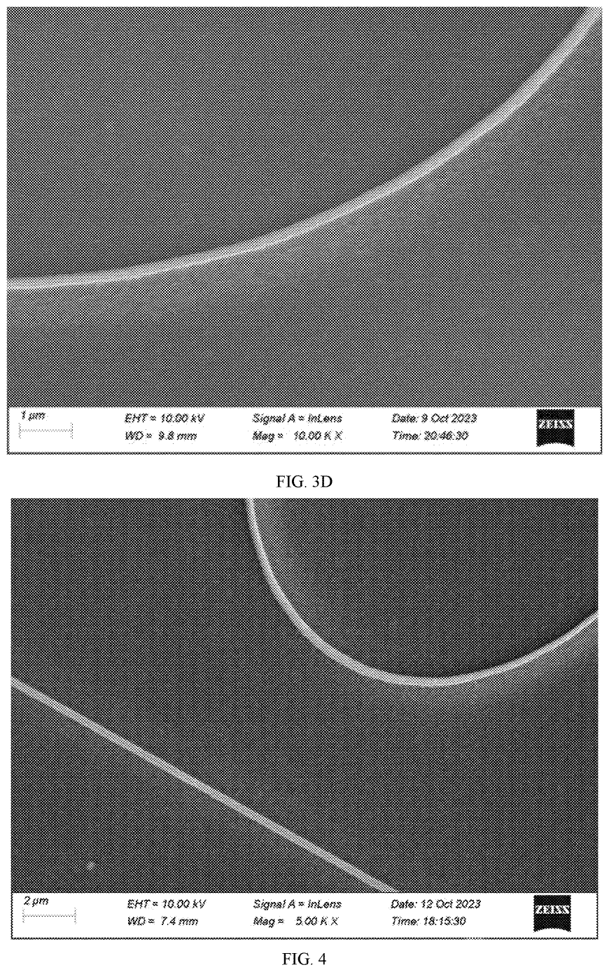

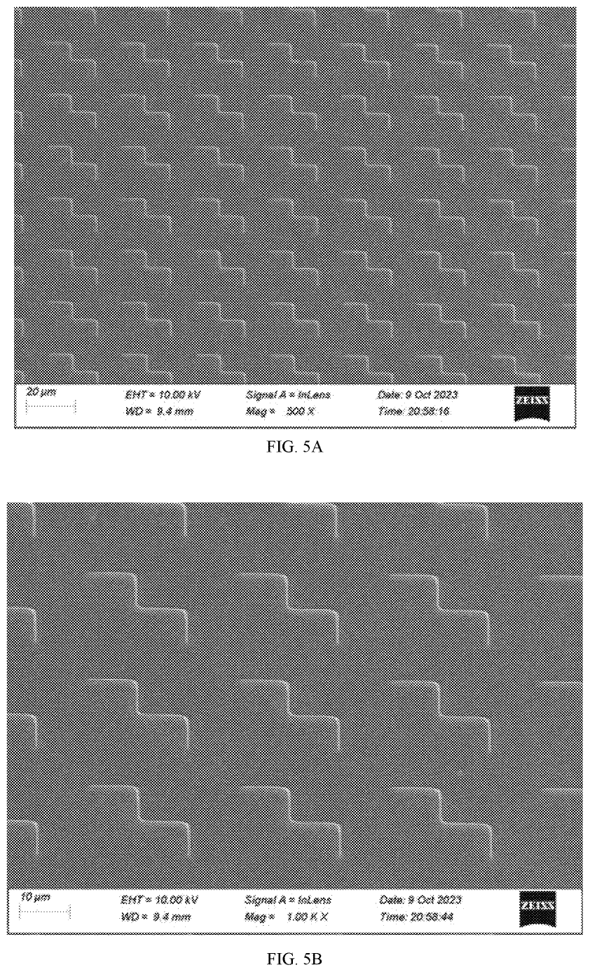

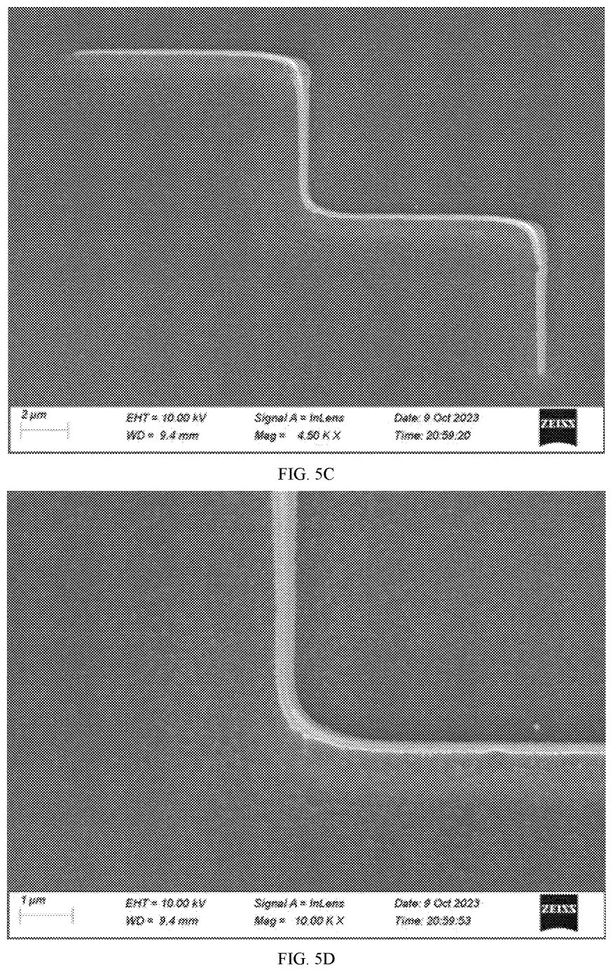

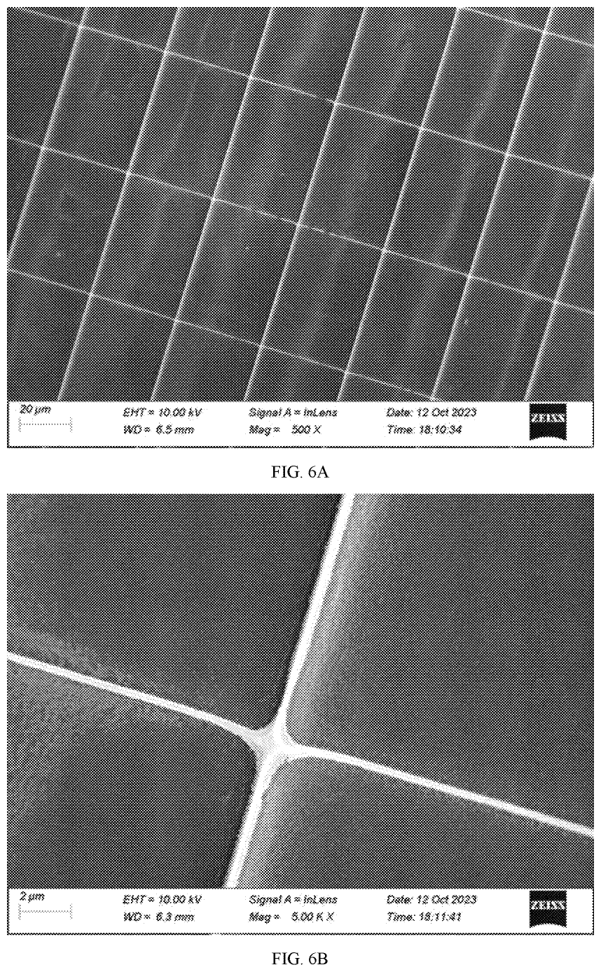

FIGS. 2A-2D, 3A-3D, 4, 5A-5D, and 6A-6B correspond to SEM images of straight-line patterns, circular arc patterns, the combined pattern of a circular arc and a straight line, zigzag patterns, and grid-line patterns transferred into a substrate according to Examples 1-5 of the present disclosure, respectively. The feature sizes of the patterns transferred into the substrate are significantly reduced compared to the original pattern sizes. As shown in the figures, the transferred patterns exhibit high precision and high edge definition, maintaining their high precision and high edge definition even at high magnifications.

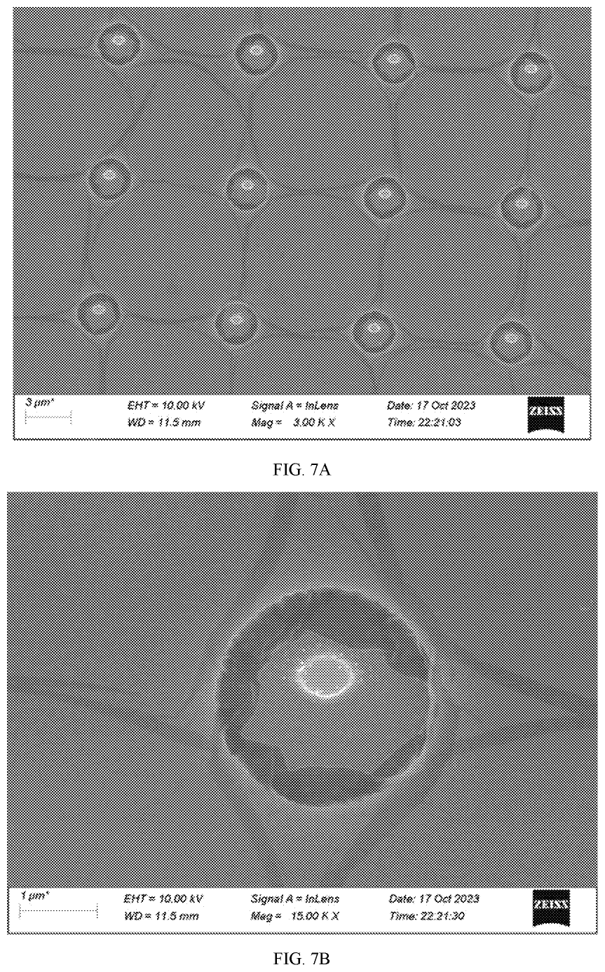

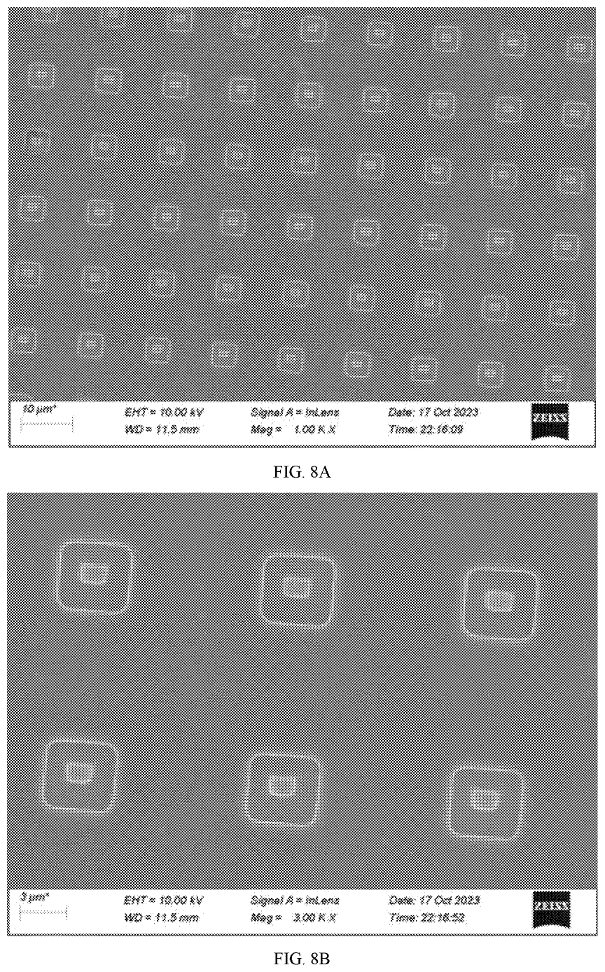

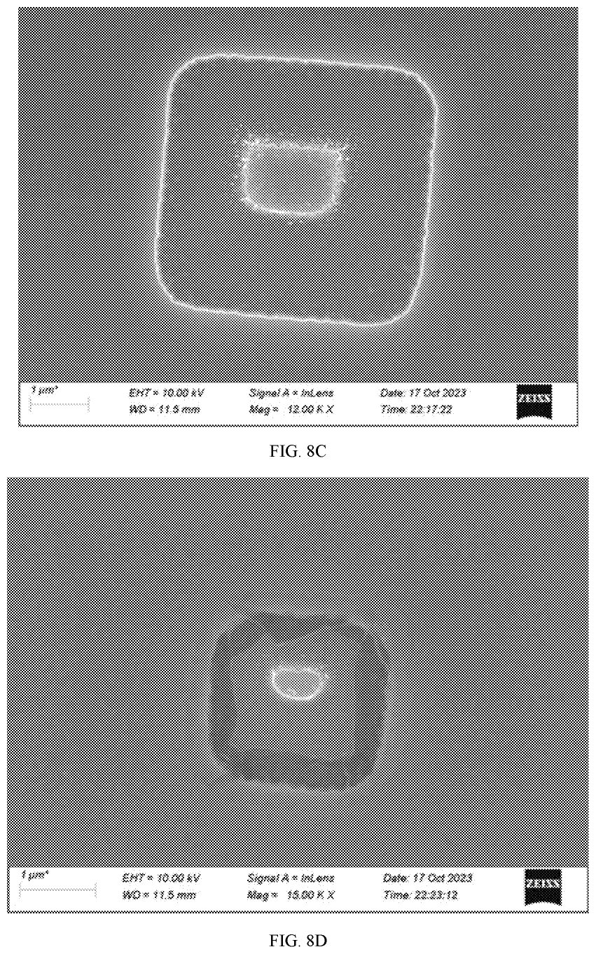

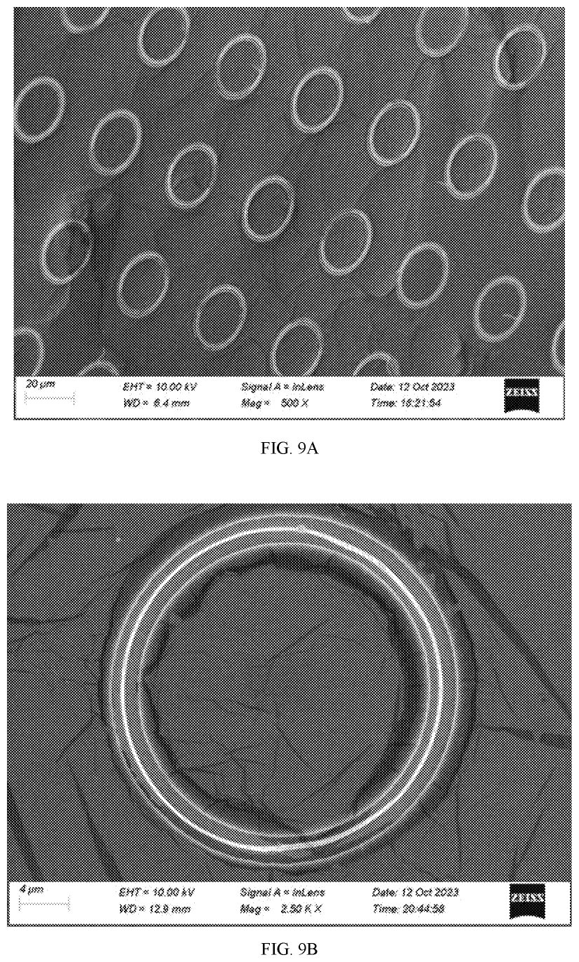

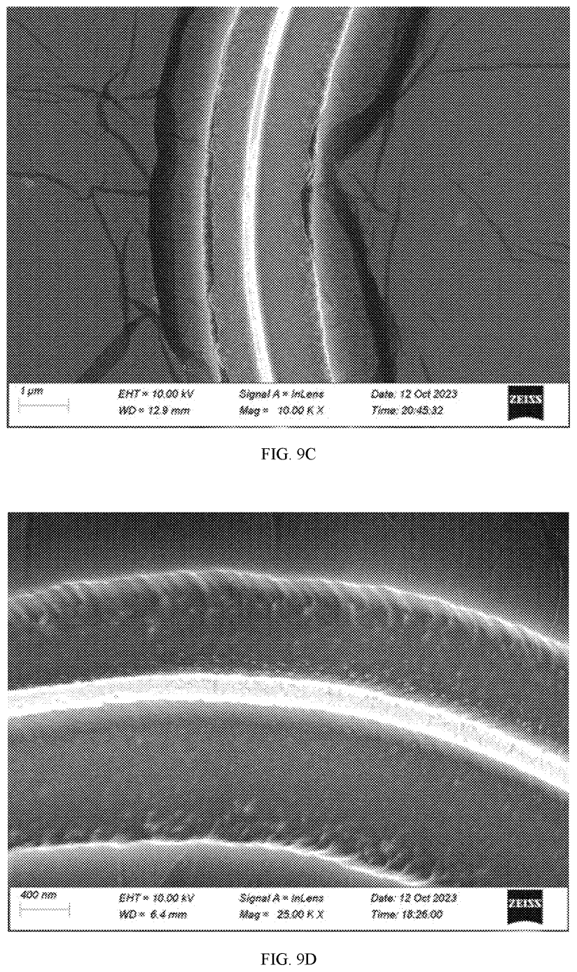

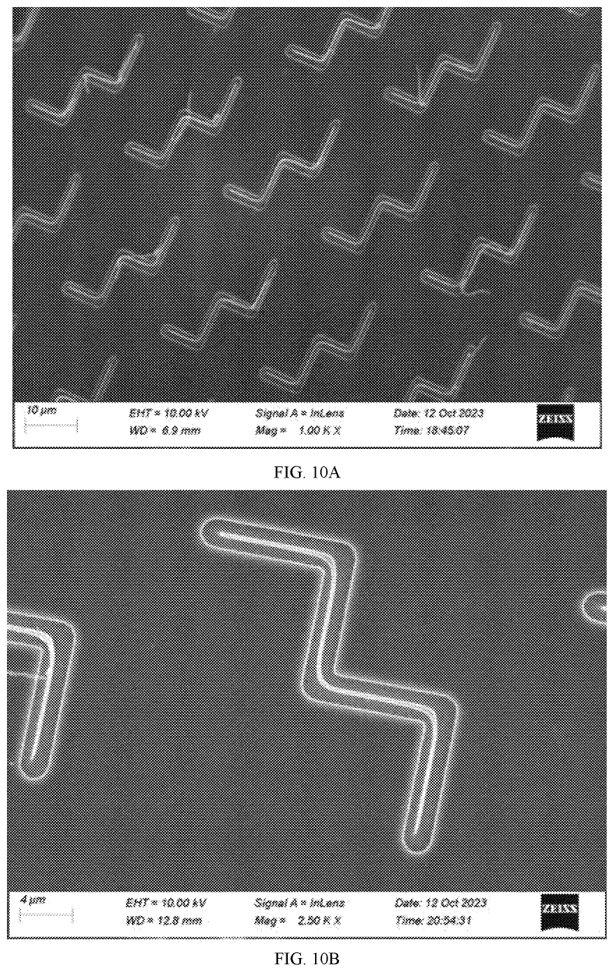

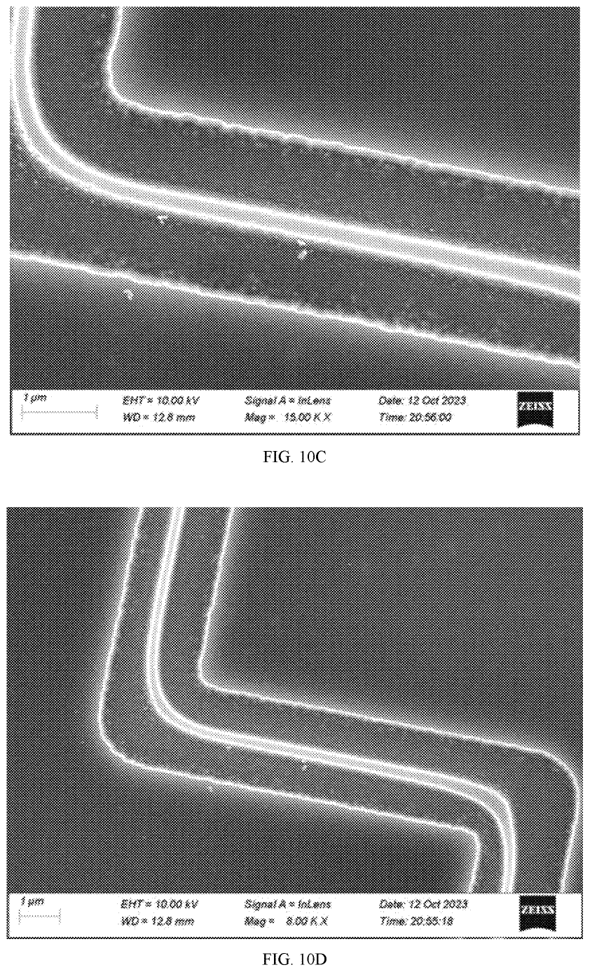

FIGS. 7A-7B, 8A-8D, 9A-9D, 10A-10D, 11A-11C, 12A-12C, and 13A-13B correspond to SEM images of circular dot array patterns, square dot array patterns, circular arc patterns, zigzag patterns, triangular outline patterns, grid-line patterns, and combined patterns of circular arcs and straight lines transferred into the substrate according to Examples 6-12 of the present disclosure, respectively. As shown in the figures, structures with small feature sizes may be formed based on patterns with large feature sizes and are transferred together, achieving a significant reduction in feature size while also obtaining a density multiplication effect. The transferred patterns exhibit high precision and high edge definition, maintaining their high accuracy and high edge definition even under high magnification.

FIGS. 14A-14B are SEM images of cross-sections of structures printed according to the additive manufacturing method (steps (1)-(3)) in Example 8 of the present disclosure after ion beam cutting. As shown in FIG. 14A, the edges of the printed structure are very blurry. Moreover, as indicated by the dashed line in FIG. 14B, the sidewall of the printed structure exhibits an angle of approximately 45 degrees, resulting in low verticality. FIGS. 14C-14D are SEM images of cross-sections of the pattern transferred into the substrate according to the patterning method (steps (4)-(6)) in Example 8 of the present disclosure after ion beam cutting. It can be seen that, as shown in FIG. 14C, the sidewall of the transferred pattern is approximately 90 degrees, indicating improved sidewall verticality. Furthermore, as shown in FIG. 14D, the edges of the transferred pattern are clearly visible.

FIGS. 15A-15B are SEM images at different magnifications of line structures printed by the additive manufacturing method (steps (1)-(3)) according to Example 1 of the present disclosure. It can be seen that the printed structure exhibits a noticeable halo at the bottom, and the boundaries of the structures are not sharp. FIGS. 15C-15D are SEM images of circular arc patterns and triangular outline patterns transferred into the substrate according to the patterning methods in Examples 8 and 10 of the present disclosure, in which very distinct boundaries of the patterns can be observed. Moreover, the patterns in FIGS. 15C-15D under higher magnification show sharper boundaries compared to those in FIGS. 15A-15B, indicating that the edge definition of the transferred patterns has been significantly improved.

FIGS. 16A-16B and FIGS. 17A-17B correspond to SEM images at different magnifications of the structures printed according to the additive manufacturing method (steps (1)-(2)) in Examples 13-14 of the present disclosure. It can be seen that the feature size of the printed structures is significantly reduced, enabling low-cost, efficient, and large-area three-dimensional structure printing. According to the additive manufacturing method of the present disclosure, it is not necessary to electrically connect the substrate, allowing the use of an insulating substrate. Effects comparable to or even better than those of structures printed according to the method described in CN113478809B can be achieved merely by controlling the electric field strength at the printing position (i.e., the electric field strength at the position where the electric field converges).

1. A micro-nanoscale additive manufacturing method, which
guides directional migration of a charged phase dispersed in a gas by utilizing an electric field effect,
allows the charged phase dispersed in the gas pass through a through-hole channel in a layer with opening pattern arrays and then migrate and stack onto the substrate to form a printed structure,
wherein the printed structure has a feature size smaller than that of the through-hole channel; wherein the substrate is an insulating substrate, and an electric field strength at a printing position is controlled to be not less than 15000 V/cm, wherein the direction of the electric field is either positive or negative.

2. The additive manufacturing method according to claim 1, wherein the insulating substrate is a silicon dioxide substrate, a glass substrate, or a plastic substrate.

3. The additive manufacturing method according to claim 1, wherein the method satisfies one or more of the following conditions:
(1) the electric field effect is generated by applying an external electric field, and the external electric field has a strength of 1-10000 V/cm, wherein the direction of the electric field is either positive or negative;
(2) the charged phase dispersed in the gas is a charged liquid and/or solid substance dispersed in the gas, and the material of the charged phase dispersed in the gas is one or more selected from the group consisting of inorganic materials, organic materials, and composite materials;
(3) the size of the charged phase dispersed in the gas is 0.1 nm to 10 μm;
(4) the charged phase dispersed in the gas is prepared by a discharge plasma technology, a gas atomization method, or an electrospray method;
(5) the layer with opening pattern arrays is a mask with opening pattern arrays, or a layer with opening pattern arrays fabricated by photolithography;
(6) the material of the layer with opening pattern arrays is a dielectric or conductive layer;
(7) a spacing between the layer with opening pattern arrays and the substrate is greater than or equal to 0;
(8) the opening patterns are various simple patterns or complex patterns, the simple patterns being dots, straight lines, or circular arcs, and the complex patterns being intersecting lines, zigzag lines, dot arrays, square arrays, polygons, or a combined pattern of one or more of the foregoing patterns and the simple patterns;
(9) the feature size of the printed structure is 0.1 nm to 10 μm.

4. The additive manufacturing method according to claim 3, wherein the method satisfies one or more of the following conditions:
(1) the material of the charged phase dispersed in the gas is a conductor material or a semiconductor material;
(2) the organic material is a polymer material or a biomolecular material;
(3) the material of the layer with opening pattern arrays is silicon nitride, silicon oxide, or photoresist;
(4) the material of the layer with opening pattern arrays is a metallic material;
(5) the spacing between the layer with opening pattern arrays and the substrate is 0-50 μm;
(6) the feature size of the printed structure is 0.1 nm to 1000 nm.

5. The additive manufacturing method according to claim 4, wherein the method satisfies one or two of the following conditions:
(1) the conductor material is a metallic material, a non-metallic element in its elemental form, or a compound formed from a non-metallic element in its elemental form and a metal;
(2) the feature size of the printed structure is 1000 nm, 800 nm, 400 nm, 300 nm, or 200 nm.

6. The additive manufacturing method according to claim 5, wherein the method satisfies one or more of the following conditions:
(1) the non-metallic element is one or more selected from the group consisting of boron, carbon, nitrogen, oxygen, silicon, and arsenic;
(2) the feature size of the opening pattern is a factor of 4, 5, 6, 10, or 16 to the feature size of the printed structure; and
(3) the metallic material is an elemental metal or an alloy.

7. The additive manufacturing method according to claim 3, wherein the method satisfies any one of the following conditions:
(1) when the material of the printed pattern is conductive or semiconductive, the charged phase dispersed in the gas is prepared by the discharge plasma technology;
(2) when the material of the dispersed phase is a solution, the charged phase dispersed in the gas is prepared by the gas atomization method or the electrospray method.

8. The additive manufacturing method according to claim 6, wherein the metallic element in the metallic material is one or more selected from the group consisting of magnesium, aluminum, titanium, vanadium, chromium, manganese, iron, cobalt, nickel, copper, zinc, gallium, germanium, yttrium, zirconium, niobium, molybdenum, technetium, ruthenium, rhodium, palladium, silver, cadmium, indium, tin, antimony, hafnium, tantalum, tungsten, rhenium, iridium, platinum, gold, lead, and bismuth.

9. The additive manufacturing method according to claim 1, wherein the printing position refers to the position on the substrate where printing starts after electric field lines finally converge; the electric field lines start to converge when passing through the channel, and the convergence strength of the electric field lines remains unchanged until reaching the substrate.

10. The additive manufacturing method according to claim 1, wherein the printing position refers to the position on the substrate where printing starts after electric field lines finally converge, and the electric field strength at the printing position is 15000-30000 V/cm, wherein the direction of the electric field is either positive or negative.

11. The additive manufacturing method according to claim 1, wherein the feature size of the opening pattern is a factor of 1 to 100, 1 to 20, or 2 to 20 to the feature size of the printed structure.

12. A micro-nanoscale patterning method, comprising: transferring a printed structure formed on a substrate into the substrate;
wherein the printed structure is produced by the following additive manufacturing method:
guiding directional migration of a charged phase dispersed in a gas by utilizing an electric field effect, and
allowing the charged phase dispersed in the gas pass through a through-hole channel in a layer with opening pattern arrays and then migrate and stack onto the substrate to form a printed structure, wherein the printed structure has a feature size smaller than that of the through-hole channel;
the substrate is a conductive substrate or an insulating substrate; when the substrate is a conductive substrate, the substrate is connected to an external circuit; when the substrate is an insulating substrate, an electric field strength at a printing position is controlled to be not less than 15000 V/cm, wherein the direction of the electric field is either positive or negative;
wherein the transferring is performed in any one of the following methods:
(1) on a substrate formed with the printed structure only, etching the part of the substrate that is not covered with the printed structure, and then removing the printed structure from the substrate; and
(2) on a substrate covered with the layer with opening pattern arrays and formed with the printed structure, etching the part of the substrate that is not covered with the printed structure and is not covered with the layer with opening pattern arrays, and then removing the layer with opening pattern arrays and the printed structure from the substrate.

13. The patterning method according to claim 12, wherein the method satisfies one or more of the following conditions:
(1) the conductive substrate is a silicon substrate, a silicon nitride substrate, or a silicon carbide substrate;
(2) when the substrate is a conductive substrate and connected to an external circuit, the electric field strength at the printing position is 1-30000 V/cm, wherein the direction of the electric field is either positive or negative;
(3) in method (1) of the transferring, before the etching, a step of removing the layer with opening pattern arrays may further be included, so as to prepare the substrate having only the printed structure;
(4) in method (2) of the transferring, the layer with opening pattern arrays is removed first, and then the printed structure is removed;
(5) the etching is selective etching or non-selective etching;
(6) a ratio of a depth of the etching to a feature size of the printed structure is 1 to 10;
(7) when the material of the layer with opening pattern arrays is a photoresist, the layer with opening pattern arrays is removed by plasma bombardment or solvent dissolution;
(8) when the layer with opening pattern arrays is a mask, the mask is moved away from the substrate having the printed structure by a nanoscale translation stage;
(9) when the material of the printed structure is a metal, the printed structure is removed using a metal etchant;
(10) the patterning method may form a pattern with an area of not less than 8 mm² in a single operation.

14. The patterning method according to claim 13, wherein the method satisfies one or more of the following conditions:
(1) the conductive substrate is a silicon substrate;
(2) the etching is reactive ion beam selective etching;
(3) the ratio of the depth of the etching to the feature size of the printed structure is 1 to 4, 1, 2, or 4; and
(4) when the material of the printed structure is gold, the printed structure is removed using a potassium iodide solution.

15. The patterning method according to claim 12, wherein, before the transferring, a step of obtaining the printed structure using the following additive manufacturing method is further included:
guiding directional migration of a charged phase dispersed in a gas by utilizing an electric field effect, and allowing the charged phase dispersed in the gas pass through a through-hole channel in a layer with opening pattern arrays and then migrate and stack onto the substrate to form a printed structure, the printed structure has a feature size smaller than that of the through-hole channel;
the substrate is a conductive substrate or an insulating substrate; when the substrate is a conductive substrate, the substrate is connected to an external circuit; when the substrate is an insulating substrate, an electric field strength at a printing position is controlled to be not less than 15000 V/cm, wherein the direction of the electric field is either positive or negative.

16. The patterning method according to claim 12, wherein the printing position refers to the position on the substrate where printing starts after electric field lines finally converge; the electric field lines start to converge when passing through the channel, and the convergence strength of the electric field lines remains unchanged until reaching the substrate.

17. The patterning method according to claim 12, wherein the printing position refers to the position on the substrate where printing starts after electric field lines finally converge, and the electric field strength at the printing position is 15000-30000 V/cm, wherein the direction of the electric field is either positive or negative.

18. The patterning method according to claim 12, wherein the substrate is an insulating substrate, the insulating substrate is a silicon dioxide substrate, a glass substrate, or a plastic substrate.

19. The patterning method according to claim 12, wherein the feature size of the opening pattern is a factor of 1 to 100, 1 to 20, or 2 to 20 to the feature size of the printed structure.
